(19) United States
(12) Patent Application Publication
(10) Pub. No.: US 2025/0031467 A1
(43) Pub. Date: Jan. 23, 2025

(54) IMAGE SENSOR

(71) Applicant: SAMSUNG ELECTRONICS CO., LTD., Suwon-si (KR)

(72) Inventors: Sooyoung Kang, Suwon-si (KR); Doowon Kwon, Suwon-si (KR); Yongjun Kim, Suwon-si (KR); Sol Yoon, Suwon-si (KR); Keunhyoung Park, Suwon-si (KR); Dongjun Oh, Suwon-si (KR)

(21) Appl. No.: 18/737,207

(22) Filed: Jun. 7, 2024

(30) Foreign Application Priority Data
Jul. 19, 2023 (KR) 10-2023-0094017

(51) Int. Cl. H01L 27/146; H04N 25/79

(52) U.S. Cl. CPC H01L 27/14614; H01L 27/14634; H01L 27/14636; H01L 27/14645; H04N 25/79

(57) ABSTRACT

An image sensor is described comprising a first, a second, and a third stack mounted together. The first stack includes a first semiconductor substrate with a photoelectric conversion region, a floating diffusion region, and a transmission gate. The photoelectric conversion region absorbs light, and the charges freed by the light absorption are stored in the floating diffusion region prior to being transferred to other circuitry by the transmission gate. The transmission gate comprises an etch stop film on an upper surface and on a sidewall. The second stack, attached to the first stack, includes a second semiconductor substrate in which is located a pixel gate. The pixel gate is electrically connected with the floating diffusion region and further comprises a gate spacer on a sidewall of the pixel gate. The third stack, attached to the second stack, includes a logic transistor.

### CROSS-REFERENCE TO RELATED APPLICATION

This application is based on and claims priority under 35 U.S.C. § 119 to Korean Patent Application No. 10-2023-0094017, filed on Jul. 19, 2023, in the Korean Intellectual Property Office, the disclosure of which is incorporated by reference herein in its entirety.

### BACKGROUND

Image sensors are devices for converting images into electrical signals. Image sensors include a plurality of pixels, which each receive light incident thereon to convert the light into an electrical signal and each include a photodiode region. Because the size of each pixel decreases along with the increasing degree of integration of image sensors, an electrical connection component of a pixel circuit for driving each pixel is also reduced in size causing problems. For example, too much noise may be generated or the photoelectric conversion efficiency, such as a conversion gain, may decrease.

### SUMMARY

An image sensor having excellent image quality even with a small pixel size is described.

In general, in some aspects, the subject matter of the present disclosure is directed to an image sensor including: a first stack, which includes a first semiconductor substrate including a first surface and a second surface that is opposite to the first surface, a photoelectric conversion region in the first semiconductor substrate, a floating diffusion region arranged in the first semiconductor substrate and configured to store charges transferred from the photoelectric conversion region, a transmission gate on the first surface of the first semiconductor substrate, and a first etch stop film arranged on an upper surface and a sidewall of the transmission gate and on the first surface of the first semiconductor substrate; a second stack, which includes a second semiconductor substrate including a first surface and a second surface that is opposite to the first surface, a pixel gate arranged on the first surface or the second surface of the second semiconductor substrate and electrically connected with the floating diffusion region, and a gate spacer on a sidewall of the pixel gate; and a third stack, which is attached to the second stack and includes a logic transistor configured to provide signals to the pixel gate and the transmission gate.

In general, in some aspects, the subject matter of the present disclosure is directed to an image sensor including: a first stack, which includes a first semiconductor substrate including a first surface and a second surface that is opposite to the first surface, a photoelectric conversion region in the first semiconductor substrate, a floating diffusion region arranged in the first semiconductor substrate and configured to store charges transferred from the photoelectric conversion region, a transmission gate on the first surface of the first semiconductor substrate, and a first etch stop film arranged on an upper surface and a sidewall of the transmission gate and on the first surface of the first semiconductor substrate; a second stack, which includes a second semiconductor substrate including a first surface and a second surface that is opposite to the first surface and a pixel gate arranged on the first surface or the second surface of the second semiconductor substrate and electrically connected with the floating diffusion region; and a third stack, which is attached to the second stack and includes a logic transistor configured to provide signals to the pixel gate and the transmission gate, wherein a portion of the first etch stop film, which is arranged on the sidewall of the transmission gate, has a sidewall extending perpendicular to the first surface of the first semiconductor substrate.

In general, according to some aspects, the subject matter of the present disclosure is directed to an image sensor including: a first stack; a second stack attached to the first stack; and a third stack attached to the second stack, wherein the first stack includes a first semiconductor substrate including a first surface and a second surface that is opposite to the first surface, a photoelectric conversion region in the first semiconductor substrate, a floating diffusion region arranged in the first semiconductor substrate and configured to store charges transferred from the photoelectric conversion region, a transmission gate arranged on the first surface of the first semiconductor substrate and having a portion that is arranged in a transmission trench extending to the inside of the first semiconductor substrate, a first etch stop film arranged on an upper surface and a sidewall of the transmission gate and on the first surface of the first semiconductor substrate, and a passivation layer arranged between the first etch stop film and each of the upper surface and the sidewall of the transmission gate and between the first etch stop film and the first surface of the first semiconductor substrate. The second stack includes a second semiconductor substrate including a first surface and a second surface that is opposite to the first surface, a pixel gate arranged on the first surface or the second surface of the second semiconductor substrate and electrically connected with the floating diffusion region, a gate spacer on a sidewall of the pixel gate, and a second etch stop film arranged on an upper surface of the pixel gate and on a sidewall of the gate spacer. The third stack includes a logic transistor configured to provide signals to the pixel gate and the transmission gate.

### BRIEF DESCRIPTION OF THE DRAWINGS

Embodiments will be more clearly understood from the following detailed description taken in conjunction with the accompanying drawings in which:

FIG. 1 is a perspective view schematically illustrating an example of an image sensor;

FIG. 2 is a layout diagram illustrating a first stack corresponding to one pixel of FIG. 1;

FIG. 3 is a layout diagram illustrating a second stack corresponding to one pixel of FIG. 1;

FIG. 4 is a cross-sectional view of the second stack of FIG. 3, taken along a line A1-A1′ of FIG. 3;

FIG. 5 is an enlarged view of a region CX1 of FIG. 4;

FIG. 6 is an enlarged view of a region CX2 of FIG. 4;

FIG. 7 is an equivalent circuit diagram of a pixel of an example of an image sensor;

FIG. 8 is a layout diagram of a first stack of an example of an image sensor;

FIG. 9 is a layout diagram illustrating an example of an image sensor;

FIG. 10 is a cross-sectional view of the image sensor of FIG. 9;

FIG. 11 is a layout diagram illustrating an example of an image sensor;

FIG. 12 is a cross-sectional view of the image sensor of FIG. 11;

FIG. 13 is a layout diagram illustrating an example of an image sensor;

FIG. 14 is a layout diagram illustrating an example of an image sensor;

FIG. 15 is a cross-sectional view illustrating an example of an image sensor; and

FIG. 16 is a block diagram illustrating a configuration of an example of an image sensor.

### DETAILED DESCRIPTION OF THE EMBODIMENTS

Hereinafter, implementations of the present disclosure will be described in detail with reference to the accompanying drawings.

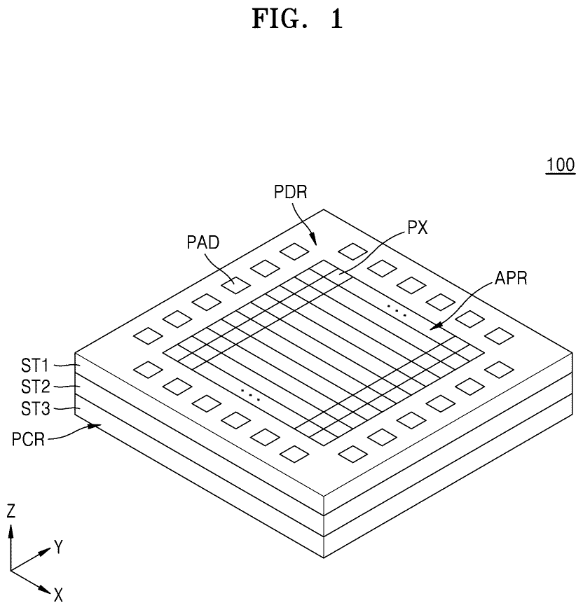

FIG. 1 is a perspective view schematically illustrating an example of an image sensor 100.

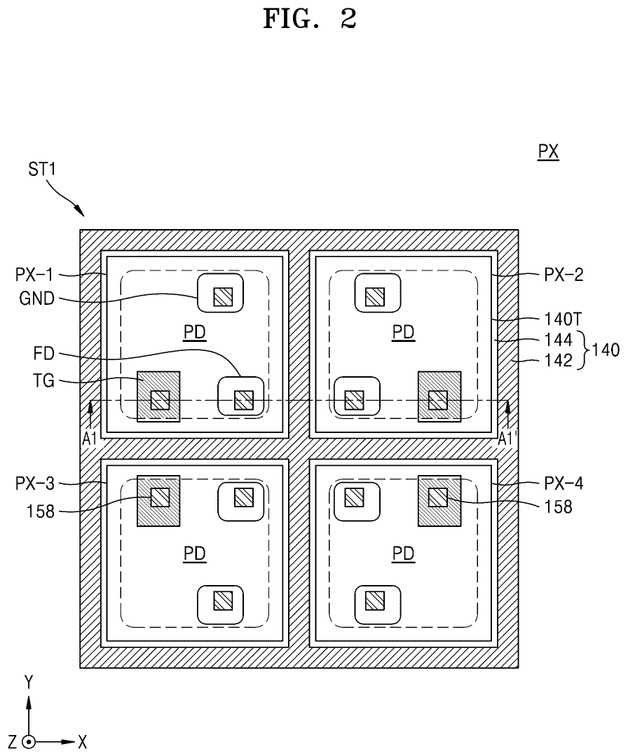

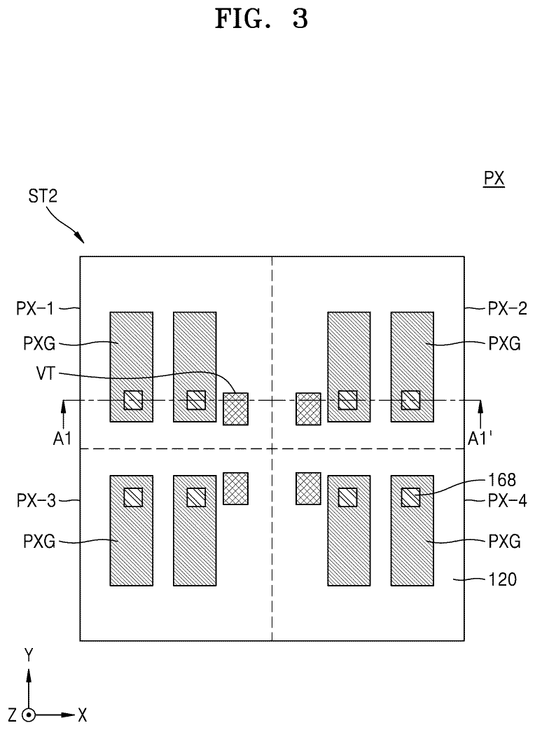

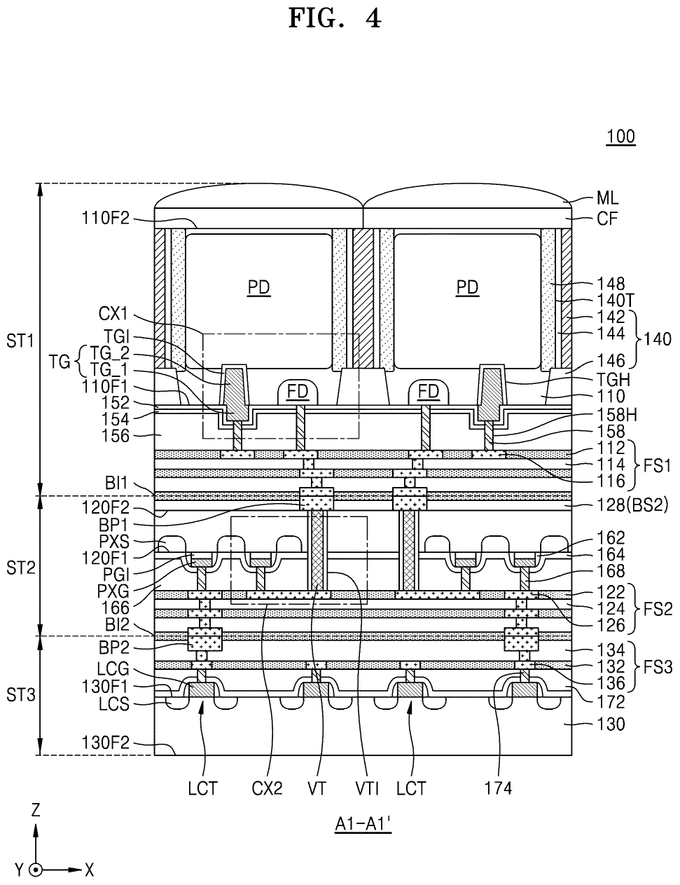

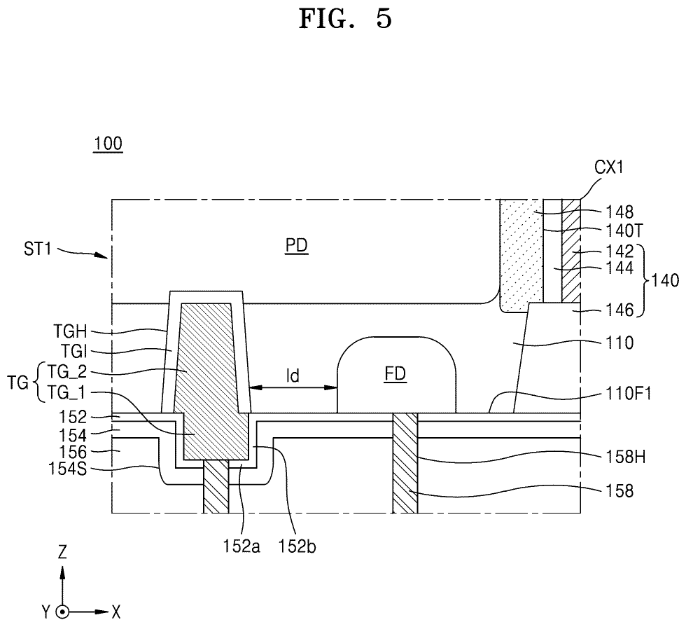

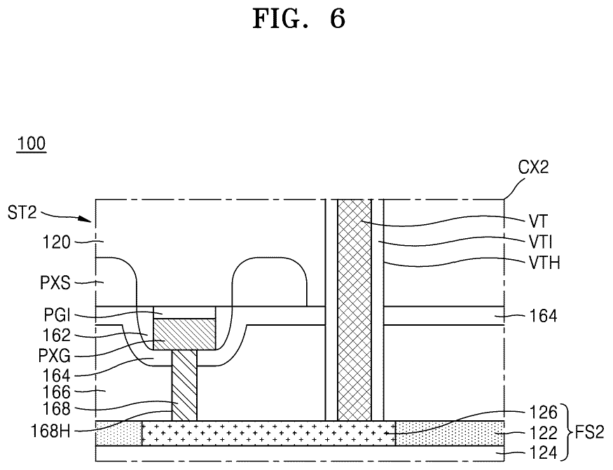

FIG. 2 is a layout diagram illustrating a first stack ST1 corresponding to one pixel PX of FIG. 1, and FIG. 3 is a layout diagram illustrating a second stack ST2 corresponding to one pixel PX of FIG. 1. FIG. 4 is a cross-sectional view of the second stack ST2, taken along a line A1-A1′ of FIG. 3. FIG. 5 is an enlarged view of a region CX1 of FIG. 4. FIG. 6 is an enlarged view of a region CX2 of FIG. 4.

Referring to FIGS. 1 to 6, the image sensor 100 includes a stacked image sensor in which the first stack ST1, the second stack ST2, and a third stack ST3 are stacked in the vertical direction.

An active pixel region APR may be arranged in a central portion of the image sensor 100, and a plurality of pixels PX may be arranged in the active pixel region APR. The plurality of pixels PX may each be a region receiving light from outside the image sensor 100 and converting the light into an electrical signal. The plurality of pixels PX may be arranged in the first stack ST1 and the second stack ST2. For example, a photoelectric conversion region PD for receiving external light may be arranged in the first stack ST1, and transistors constituting a pixel circuit for converting photocharges, which accumulate in the photoelectric conversion region PD, into electrical signals may be arranged in the second stack ST2.

A pad region PDR may be arranged on at least one side of the active pixel region APR, for example, four sides of the active pixel region APR in a plan view. A plurality of pads PAD may be arranged in the pad region PDR and may be configured to transmit electrical signals to and receive electrical signals from an external device or the like.

A peripheral circuit region PCR may include a logic circuit block and/or a memory device. For example, the logic circuit block may include a plurality of logic transistors LCT and may provide a certain signal to each pixel PX of the active pixel region APR or control an output signal of each pixel PX. For example, a logic transistor LCT may include at least one of a row decoder, a row driver, a column decoder, a timing generator, a correlated double sampler (CDS), an analog-to-digital converter, and an input/output (I/O) buffer.

The active pixel region APR may include the plurality of pixels PX, and a plurality of photoelectric conversion regions PD may be respectively arranged in the plurality of pixels PX. In the active pixel region APR, the plurality of pixels PX may be arranged in a matrix to form rows and columns in a first direction (X direction), which is parallel to an upper surface of a first semiconductor substrate 110, and a second direction (Y direction), which is perpendicular to the first direction and parallel to the upper surface of the first semiconductor substrate 110. Some of the plurality of pixels PX may each include an optical black pixel (not shown). The optical black pixel may function as a reference pixel for the active pixel region APR and perform a function of automatically correcting a dark signal.

The first stack ST1 may include a first semiconductor substrate 110 including a first surface 110F1 and a second surface 110F2, a photoelectric conversion region PD and a floating diffusion region FD, which are formed in the first semiconductor substrate 110, a transmission gate TG and a first frontside structure FS1, which are arranged on the first surface 110F1 of the first semiconductor substrate 110, and a color filter CF and a micro-lens ML, which are arranged on or over the second surface 110F2 of the first semiconductor substrate 110.

The second stack ST2 may include a second semiconductor substrate 120 including a first surface 120F1 and a second surface 120F2, a pixel transistor and a second frontside structure FS2, which are arranged on or over the first surface 120F1 of the second semiconductor substrate 120, and a backside structure BS2 arranged on the second surface 120F2 of the second semiconductor substrate 120.

The third stack ST3 may include a third semiconductor substrate 130 including a first surface 130F1 and a second surface 130F2, and a logic transistor LCT and a third frontside structure FS3, which are arranged on or over the first surface 130F1 of the third semiconductor substrate 130.

The second stack ST2 may be arranged between the first stack ST1 and the third stack ST3. For example, the second frontside structure FS2 of the second stack ST2 may be arranged to face the third frontside structure FS3 of the third stack ST3 and the backside structure BS2 of the second stack ST2 may be arranged to face the first frontside structure FS1 of the first stack ST1. The first stack ST1 and the second stack ST2 may be attached to each other by a first bonding insulating layer BI1 arranged therebetween, and the second stack ST2 and the third stack ST3 may be attached to each other by a second bonding insulating layer BI2 arranged therebetween. In some implementations, a first bonding pad BP1 may be further arranged between the first stack ST1 and the second stack ST2 such that the first bonding pad BP1 is surrounded by the first bonding insulating layer BI1, and a second bonding pad BP2 may be further arranged between the second stack ST2 and the third stack ST3 such that the bonding pad BP2 is surrounded by the second bonding insulating layer BI2.

In some implementations, the first to third semiconductor substrates 110, 120, and 130 may each include a P-type semiconductor substrate. For example, at least one of the first to third semiconductor substrates 110, 120, and 130 may include a P-type silicon substrate. In some implementations, at least one of the first to third semiconductor substrates 110, 120, and 130 may include a P-type bulk substrate and a P-type or N-type epitaxial layer grown on the P-type bulk substrate, or in some implementations, the at least one of the first to third semiconductor substrates 110, 120, and 130 may include an N-type bulk substrate and a P-type or N-type epitaxial layer grown on the N-type bulk substrate. In some implementations, the second semiconductor substrate 120 may include a portion having a silicon-on-insulator (SOI) structure, for example, a silicon layer having an SOI structure.

In the active pixel region APR, a pixel isolation structure 140 may be arranged in the first stack ST1. The plurality of pixels PX may be defined by the pixel isolation structure 140. The pixel isolation structure 140 may include a conductive layer 142, an insulating liner 144, and an upper insulating layer 146. The conductive layer 142 may be arranged in a pixel trench 140T, which passes through the first semiconductor substrate 110. The insulating liner 144 may be arranged on an inner wall of the pixel trench 140T passing through the first semiconductor substrate 110 and may be arranged between the conductive layer 142 and the first semiconductor substrate 110 to extend from the first surface 110F1 to the second surface 110F2 of the first semiconductor substrate 110. The upper insulating layer 146 may be arranged in a portion of the pixel trench 140T, which is adjacent to the first surface 110F1 of the first semiconductor substrate 110.

In some implementations, the conductive layer 142 may include at least one of doped polysilicon, a metal, a metal silicide, a metal nitride, or a metal-containing film. The insulating liner 144 may include an insulating material, such as silicon oxide, silicon nitride, or silicon oxynitride. The upper insulating layer 146 may include an insulating material, such as silicon oxide, silicon nitride, or silicon oxynitride.

In the first stack ST1, a plurality of photoelectric conversion regions PD may be arranged in the plurality of pixels PX. The photoelectric conversion region PD may correspond to a region doped with an n-type impurity. For example, the photoelectric conversion region PD may have a potential gradient due to the difference in impurity concentration between upper and lower portions of the photoelectric conversion region PD. Alternatively, the photoelectric conversion region PD may have a structure in which a plurality of impurity regions are stacked in the vertical direction.

Optionally, a liner region 148 may be arranged in a portion of the first semiconductor substrate 110 to surround each of the plurality of photoelectric conversion regions PD. The liner region 148 may be arranged between the pixel isolation structure 140 and the photoelectric conversion region PD and may correspond to a region doped with a p-type impurity.

The floating diffusion region FD may be arranged in an inner region of the first semiconductor substrate 110, which is adjacent to the first surface 110F1 of the first semiconductor substrate 110. The floating diffusion region FD may correspond to a region in which charges transferred from the photoelectric conversion region PD are stored. A ground region GND may be arranged in an inner region of the first semiconductor substrate 110, which is adjacent to the first surface 110F1 of the first semiconductor substrate 110. In some implementations, at least a portion of the ground region GND may be surrounded by a device isolation film.

The transmission gate TG may be arranged on the first surface 110F1 of the first semiconductor substrate 110. The transmission gate TG may include a first portion TG_1 and a second portion TG_2, and here, the first portion TG_1 may be arranged on the first surface 110F1 of the first semiconductor substrate 110 and the second portion TG_2 may be arranged in a transmission trench TGH, which extends from the first surface 110F1 of the first semiconductor substrate 110 to the inside of the first semiconductor substrate 110. The second portion TG_2 may be integrally connected with the first portion TG_1 and may overlap at least a portion of the first portion TG_1 in the vertical direction (Z direction).

Because FIG. 3 illustrates an example in which the first surface 110F1 of the first semiconductor substrate 110 faces downward toward the second stack ST2 and the second surface 110F2 of the first semiconductor substrate 110 faces upward, the first portion TG_1 may be arranged at a vertical level that is lower than that of the first surface 110F1 of the first semiconductor substrate 110. For example, the distance in the vertical direction between the first portion TG_1 and the second stack ST2 may be less than the distance in the vertical direction between the first surface 110F1 of the first semiconductor substrate 110 and the second stack ST2.

In some implementations, a transmission gate insulating layer TGI may be arranged on an inner wall of the transmission trench TGH. The transmission gate insulating layer TGI may be arranged with a relatively uniform thickness between the transmission gate TG and the first semiconductor substrate 110.

The first portion TG_1 and the second portion TG_2 of the transmission gate TG may be apart from the floating diffusion region FD in the horizontal direction (for example, a first horizontal direction (X direction) or a second horizontal direction (Y direction)) by as much as a lateral distance ld. In some implementations, because the first stack ST1 does not include any other gates except for the transmission gate TG, a relatively large separation distance between the transmission gate TG and the floating diffusion region FD may be secured.

In some implementations, a passivation layer 152 may be arranged on an upper surface and a sidewall of the first portion TG_1 of the transmission gate TG and on the first surface 110F1 of the first semiconductor substrate 110 and a first etch stop film 154 may be arranged on the passivation layer 152. The first etch stop film 154 may be arranged on the passivation layer 152 to cover the upper surface and the sidewall of the first portion TG_1 of the transmission gate TG and cover the first surface 110F1 of the first semiconductor substrate 110. In some implementations, the passivation layer 152 may include silicon oxide and the first etch stop film 154 may include silicon nitride.

In some implementations, the passivation layer 152 may extend to entirely cover the first surface 110F1 of the first semiconductor substrate 110. For example, the passivation layer 152 may cover the floating diffusion region FD. The passivation layer 152 may be arranged directly on the upper surface and the sidewall of the first portion TG_1 of the transmission gate TG, and any other material layer, such as a spacer, may not be arranged on the passivation layer 152 and the upper surface and the sidewall of the first portion TG_1 of the transmission gate TG.

As shown in FIGS. 4 and 5, the passivation layer 152 may be conformally formed with a relatively low and uniform thickness on the upper surface and the sidewall of the first portion TG_1 of the transmission gate TG. For example, the passivation layer 152 may include a first portion 152a, which is arranged on the upper surface of the first portion TG_1 of the transmission gate TG, and a second portion 152b, which is arranged on the sidewall of the first portion TG_1 of the transmission gate TG, and the thickness of the first portion 152a of the passivation layer 152 may be equal to the thickness of the second portion 152b of the passivation layer 152.

The first etch stop film 154 may be conformally formed with a uniform thickness on the passivation layer 152 to cover the upper surface and the sidewall of the first portion TG_1 of the transmission gate TG.

In some implementations, at least a portion of a sidewall 154S of the first etch stop film 154 may extend perpendicular to the first surface 110F1 of the first semiconductor substrate 110. For example, a portion of the sidewall 154S of the first etch stop film 154, which is arranged on the sidewall of the first portion TG_1 of the transmission gate TG, may extend perpendicular to the first surface 110F1 of the first semiconductor substrate 110.

A first buried insulating film 156 may be formed with a relatively high thickness on the first etch stop film 154. A first contact 158 may be arranged in a first contact hole 158H, which passes through the first buried insulating film 156. The first contact hole 158H may extend in the vertical direction (Z direction) through the first buried insulating film 156 to expose the upper surface of the first portion TG_1 of the transmission gate TG, the upper surface of the floating diffusion region FD, or the upper surface of the ground region GND. The first contact 158 may be arranged in the first contact hole 158H and connected with the upper surface of the first portion TG_1 of the transmission gate TG, the upper surface of the floating diffusion region FD, or the upper surface of the ground region GND. In some implementations, the first buried insulating film 156 may include silicon oxide and the first contact 158 may include at least one of titanium (Ti), titanium nitride (TiN), ruthenium (Ru), ruthenium nitride (RuN), tungsten (W), cobalt (Co), or molybdenum (Mo).

In some implementations, the passivation layer 152 may be formed with a low thickness to conformally cover the upper surface and the sidewall of the transmission gate TG after the transmission gate TG is patterned, and then, the first etch stop film 154 may be formed on the passivation layer 152. Next, the first buried insulating film 156 may be formed on the first etch stop film 154 to have a thickness sufficient to completely cover the transmission gate TG. In an etching process for forming the first contact hole 158H by removing a portion of the first buried insulating film 156, the passivation layer 152 and the first etch stop film 154 may function as an etch stop layer.

The first frontside structure FS1 may be arranged on the first buried insulating film 156. The first frontside structure FS1 may include a plurality of first insulating layers 112, a plurality of second insulating layers 114, and a wiring layer 116. For example, a first insulating layer 112 may include silicon oxide, silicon carbon nitride, or the like, and a second insulating layer 114 may include silicon oxide, silicon carbon nitride, or the like. For example, the first insulating layer 112 and the second insulating layer 114 may, respectively, include materials having distinct etch selectivities from each other. The wiring layer 116 may be covered by the first insulating layer 112 or the second insulating layer 114 and may have a multilayered structure.

The first surface 110F1 of the first semiconductor substrate 110 may be arranged to face the second surface 120F2 of the second semiconductor substrate 110, and the first frontside structure FS1 over the first surface 110F1 of the first semiconductor substrate 110 may be arranged adjacent to the backside structure BS2 on the second surface 120F2 of the second semiconductor substrate 110. The first bonding insulating layer BI1 and the first bonding pad BP1 may be arranged in an interface region between the first frontside structure FS1 and the backside structure BS2. The first bonding insulating layer BI1 may include silicon oxide or silicon carbon nitride, and the first bonding pad BP1 may include copper.

In the active pixel region APR, the pixel transistor may be arranged in the second stack ST2. The pixel transistor may be arranged on the first surface 120F1 of the second semiconductor substrate 120. For example, the pixel transistor may include a pixel gate PXG and a source/drain region PXS. The source/drain region PXS may be arranged in a portion of the second semiconductor substrate 120, which is adjacent to the pixel gate PXG. The pixel gate PXG may include at least one of doped polysilicon, a metal, a metal silicide, a metal nitride, or a metal-containing film.

A gate insulating layer PGI may be arranged between the pixel gate PXG and the first surface 120F1 of the second semiconductor substrate 120. A gate spacer 162 may be arranged on a sidewall of the pixel gate PXG. The gate spacer 162 may include silicon nitride. The gate spacer 162 may have a curved profile such that the width of a portion of the gate spacer 162, which is adjacent to the upper surface of the pixel gate PXG, is less than the width of a portion of the gate spacer 162, which is adjacent to the bottom surface of the pixel gate PXG.

The second etch stop film 164 may be arranged on the first surface 120F1 of the second semiconductor substrate 120 to cover the pixel gate PXG and the gate spacer 162. The second etch stop film 164 may be arranged on the upper surface and the sidewall of the pixel gate PXG. The second etch stop film 164 may be arranged to directly contact the upper surface of the pixel gate PXG, and the gate spacer 162 may be arranged between the second etch stop film 164 and the sidewall of the pixel gate PXG. As the gate spacer 162 has a curved profile, a portion of the second etch stop film 164, which is in contact with the gate spacer 162, may also have a curved profile and extend on the gate spacer 162.

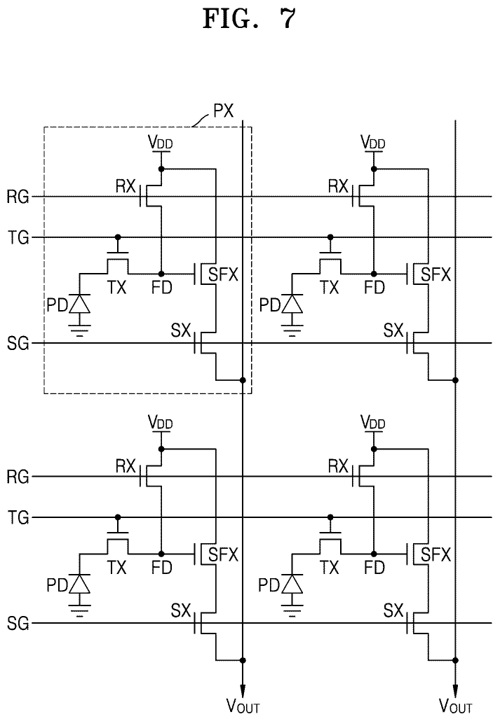

In some implementations, the pixel transistor may be configured to provide signals to the photoelectric conversion region PD and the floating diffusion region FD, which are arranged in the first stack ST1. For example, the pixel transistor may include a source follower transistor SFX (see FIG. 7), a select transistor SX (see FIG. 7), and a reset transistor RX (see FIG. 7). For example, the photoelectric conversion region PD and/or the floating diffusion region FD in the first stack ST1 in one pixel PX may be electrically connected to the pixel gate PXG in the second stack ST2 in the one pixel PX. For example, the photoelectric conversion region PD and/or the floating diffusion region FD in the first stack ST1 in one pixel PX may be electrically connected with the pixel gate PXG constituting the source follower transistor SFX (see FIG. 7), the select transistor SX (see FIG. 7), and the reset transistor RX (see FIG. 7), which are arranged in the second stack ST2 in the one pixel PX.

In some implementations, the reset transistor RX may be configured to cyclically reset charges stored in the floating diffusion region FD. The source follower transistor SFX may function as a source follower buffer amplifier and be configured to buffer a signal according to the charges stored in the floating diffusion region FD. The select transistor SX may perform switching and addressing for selecting a pixel PX.

The second stack ST2 may further include a second buried insulating film 166, which covers the pixel gate PXG, and a second contact 168, which passes through the second buried insulating film 166 and is electrically connected to the pixel gate PXG or the source/drain region PXS. The second contact 168 may be arranged in a second contact hole 168H, which passes through the second buried insulating film 166, and may include, for example, at least one of titanium (Ti), titanium nitride (TiN), ruthenium (Ru), ruthenium nitride (RuN), tungsten (W), cobalt (Co), or molybdenum (Mo).

The second frontside structure FS2 may be arranged on the second buried insulating film 166. The second frontside structure FS2 may include a plurality of first insulating layers 122, a plurality of second insulating layers 124, and a wiring layer 126. For example, a first insulating layer 122 may include silicon oxide, silicon carbon nitride, or the like, and a second insulating layer 124 may include silicon oxide, silicon carbon nitride, or the like. For example, the first insulating layer 122 and the second insulating layer 124 may respectively include materials having different etch selectivities from each other. The wiring layer 126 may be covered by the first insulating layer 122 or the second insulating layer 124 and may have a multilayered structure.

A backside insulating layer 128 may be arranged on the second surface 120F2 of the second semiconductor substrate 120. As shown in FIG. 4, the backside insulating layer 128 may be arranged on the entire area of the second surface 120F2 of the second semiconductor substrate 120 and may surround a portion of the first bonding pad BP1.

The second stack ST2 may further include a vertical via VT, which passes through the second semiconductor substrate 120 and electrically connects the backside structure BS2 to the second frontside structure FS2. The vertical via VT may be arranged in a vertical via trench VTH, which extends in the vertical direction (Z direction) through the second semiconductor substrate 120, and the first bonding pad BP1 on the second surface 120F2 of the second semiconductor substrate 120 and the wiring layer 126 of the second frontside structure FS2 may be electrically connected to each other by the vertical via VT. A vertical via insulating layer VTI may be arranged on a sidewall of the vertical via VT to electrically isolate the vertical via VT and the second semiconductor substrate 120 from each other.

In some implementations, the floating diffusion region FD of the first stack ST1 may be electrically connected to the pixel gate PXG (for example, the pixel gate PXG constituting the source follower transistor SFX) of the second stack ST2 through the vertical via VT.

In some implementations, as shown in FIGS. 2 and 3, a first pixel PX-1, a second pixel PX-2, a third pixel PX-3, and a fourth pixel PX-4 may be arranged in a matrix. Each of the first to fourth pixels PX-1, PX-2, PX-3, and PX-4 in the first stack ST1 may have a transmission gate TG and a floating diffusion region FD. The first pixel PX-1 and the third pixel PX-3, which are arranged side-by-side in the second direction (Y direction), may have shapes that are mirror-symmetric to each other, and the first pixel PX-1 and the second pixel PX-2, which are arranged side-by-side in the first direction (X direction), may have shapes that are mirror-symmetric to each other. The layout of the pixels PX shown in FIGS. 2 and 3 is provided only as an example for illustration and, for example, the sizes, shapes, positions, and the like of the transmission gate TG and the pixel gate PXG are not limited to the example shown in FIGS. 2 and 3.

The color filter CF and the micro-lens ML may be arranged on or over the second surface 110F2 of the first semiconductor substrate 110.

The third stack ST3 may include a logic transistor LCT on the first surface 130F1 of the third semiconductor substrate 130, and the logic transistor LCT may include a logic gate LCG and a source/drain region LCS. A third buried insulating layer 172 may be arranged over the first surface 130F1 of the third semiconductor substrate 130, and a third contact 174 may be arranged over the first surface 130F1 of the third semiconductor substrate 130 through the third buried insulating layer 172.

The third frontside structure FS3 may be arranged on the third buried insulating layer 172 of the third stack ST3. The third frontside structure FS3 may include at least one first insulating layer 132, at least one second insulating layer 134, and a wiring layer 136. For example, the first insulating layer 132 may include silicon oxide, silicon carbon nitride, or the like, and the second insulating layer 134 may include silicon oxide, silicon carbon nitride, or the like. For example, the first insulating layer 132 and the second insulating layer 134 may respectively include materials having different etch selectivities from each other. The wiring layer 136 may be covered by the first insulating layer 132 or the second insulating layer 134 and may have a multilayered structure.

The first surface 120F1 of the second semiconductor substrate 120 may be arranged to face the first surface 130F1 of the third semiconductor substrate 130, and the second frontside structure FS2 over the first surface 120F1 of the second semiconductor substrate 120 may be arranged adjacent to the third frontside structure FS3 over the first surface 130F1 of the third semiconductor substrate 130. The second bonding insulating layer BI2 and the second bonding pad BP2 may be arranged in an interface region between the second frontside structure FS2 and the third frontside structure FS3. The second bonding insulating layer BI2 may include silicon oxide or silicon carbon nitride, and the second bonding pad BP2 may include copper.

In some implementations, the first bonding insulating layer BI1 and the first bonding pad BP1 may be arranged in the interface region between the first frontside structure FS1 and the backside structure BS2 to allow the first stack ST1 and the second stack ST2 to be attached to each other, and the second bonding insulating layer BI2 and the second bonding pad BP2 may be arranged in the interface region between the second frontside structure FS2 and the third frontside structure FS3 to allow the second stack ST2 and the third stack ST3 to be attached to each other. That is, the first stack ST1, the second stack ST2, and the third stack ST3 may be attached to each other by a metal oxide hybrid wafer bonding method. However, in some implementations, only the first bonding insulating layer BI1 may be arranged in the interface region between the first frontside structure FS1 and the backside structure BS2 and only the second bonding insulating layer BI2 may be arranged in the interface region between the second frontside structure FS2 and the third frontside structure FS3. In this case, the first stack ST1, the second stack ST2, and the third stack ST3 may be attached to each other by an oxide-oxide wafer bonding method.

In general, due to a relatively small separation distance between a transmission gate and a floating diffusion region, a spacer is formed on a sidewall of the transmission gate, and an ion implantation process for forming the floating diffusion region is performed by using the transmission gate and the spacer as an ion implantation mask. However, etching damage may occur on a semiconductor substrate in an etching process for forming the spacer or the like, and thus, noise due to the generation of dark current in an image sensor may be increased.

However, according to the above-described implementations, the pixel gate PXG may be arranged in the second stack ST2 and the transmission gate TG and the floating diffusion region FD may be arranged in the first stack ST1. Therefore, the transmission gate TG may be apart from the floating diffusion region FD in the horizontal direction, and even when a spacer is not formed on the sidewall of the transmission gate TG, an ion implantation process for forming the floating diffusion region FD may be precisely adjusted. Therefore, because etching damage, which may occur on a semiconductor substrate in a spacer formation process, may be prevented, the generation of noise in the image sensor 100 may be reduced or prevented.

FIG. 7 is an equivalent circuit diagram of a pixel PX of an example of an image sensor.

Referring to FIG. 7, a plurality of pixels PX are arranged in a matrix. Each of the plurality of pixels PX may include a transmission transistor TX and pixel transistors. Here, the pixel transistors may include a reset transistor RX, a select transistor SX, and a source follower transistor SFX. The reset transistor RX may include a reset gate RG, the select transistor SX may include a select gate SG, and the transmission transistor TX may include a transmission gate TG.

Each of the plurality of pixels PX may further include a photoelectric conversion region PD and a floating diffusion region FD. The photoelectric conversion region PD may correspond to the photoelectric conversion region PD described with reference to FIGS. 1 to 6. The photoelectric conversion region PD may generate and accumulate photocharges in proportion to the amount of light incident from outside the pixel PX and may include a photodiode, a phototransistor, a photogate, a pinned photodiode (PPD), or a combination thereof.

The transmission gate TG may transmit charges generated in the photoelectric conversion region PD to the floating diffusion region FD. The floating diffusion region FD may receive the charges generated in the photoelectric conversion region PD and cumulatively store the charges. The source follower transistor SFX may be controlled according to the amount of photocharges accumulated in the floating diffusion region FD.

The reset transistor RX may cyclically reset the charges accumulated in the floating diffusion region FD. A drain electrode of the reset transistor RX is connected with the floating diffusion region FD, and a source electrode of the reset transistor RX is connected with a power supply voltage V_{DD}. When the reset transistor RX is turned on, the power supply voltage V_{DD} connected with the source electrode of the reset transistor RX is transferred to the floating diffusion region FD. When the reset transistor RX is turned on, the charges accumulated in the floating diffusion region FD may be released, and thus, the floating diffusion region FD may be reset.

The source follower transistor SFX is connected with a current source (not shown) located outside the plurality of pixels PX to function as a source follower buffer amplifier, amplify a change in potential in the floating diffusion region FD, and output the change in potential to an output line V_{OUT}.

The select transistor SX may select a plurality of pixels PX on a row basis, and an output voltage generated by the source follower transistor SFX when the select transistor SX is turned on may be transferred to the output line V_{OUT}.

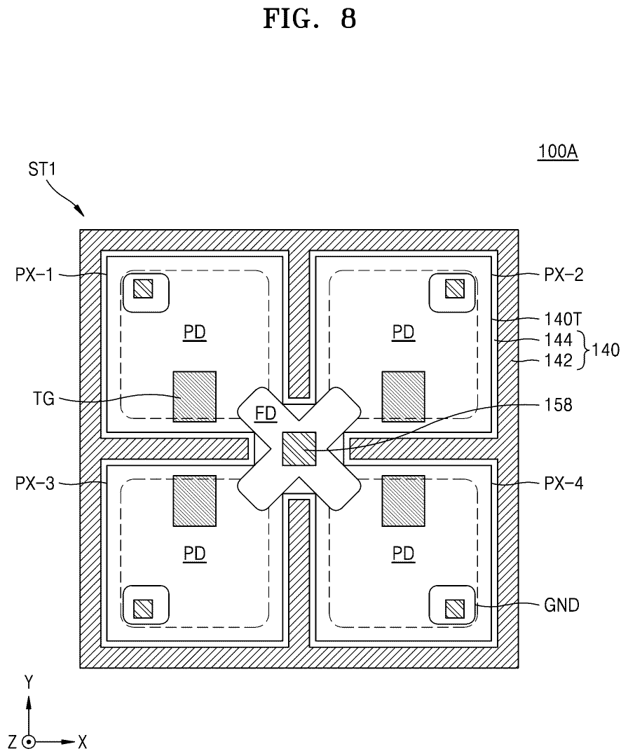

FIGS. 8 to 15 are schematic diagrams respectively illustrating image sensors. In FIGS. 8 to 15, the same reference numerals as in FIGS. 1 to 7 respectively denote the same components.

FIG. 8 is a layout diagram of the first stack ST1 of an example of an image sensor 100A.

Referring to FIG. 8, the floating diffusion region FD is shared by the first to fourth pixels PX-1 to PX-4. The pixel isolation structure 140 may not be arranged in a portion of the first semiconductor substrate 110, which vertically overlaps the floating diffusion region FD.

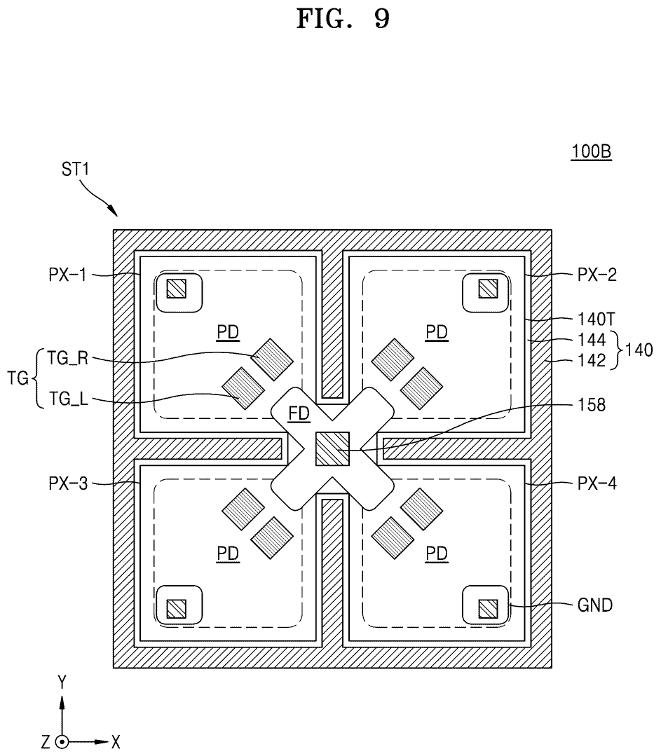

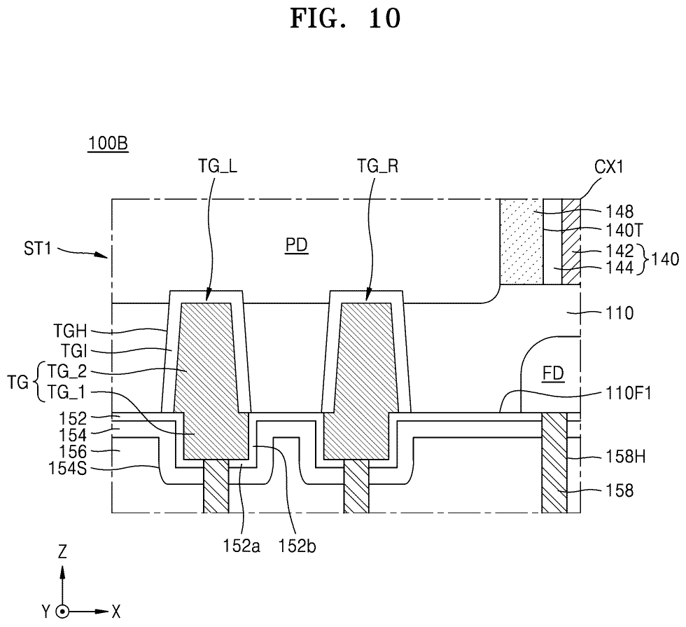

FIG. 9 is a layout diagram illustrating an example of an image sensor 100B, and FIG. 10 is a cross-sectional view of the image sensor 100B of FIG. 9.

Referring to FIGS. 9 and 10, the transmission gate TG is a dual-type transmission gate. For example, two transmission gates TG may be arranged in one pixel. For example, the transmission gate TG may include a first gate TG_L and a second gate TG_R, which are arranged apart from each other. In some implementations, as shown in FIG. 9, the first gate TG_L and the second gate TG_R may be arranged with the same separation distance from the floating diffusion region FD.

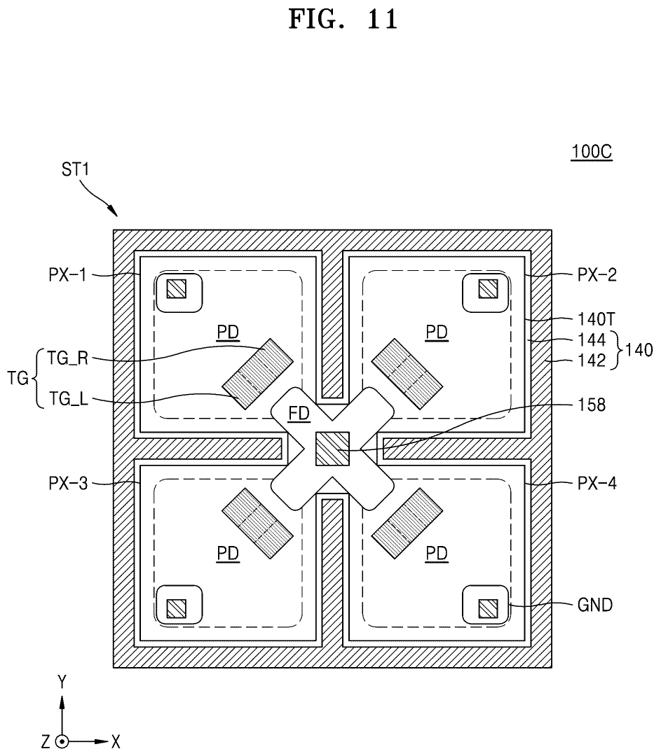

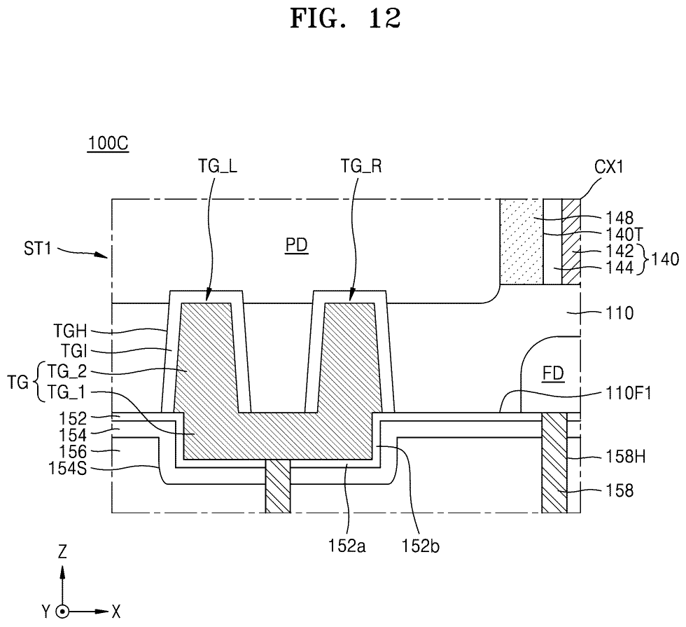

FIG. 11 is a layout diagram illustrating an example of an image sensor 100C, and FIG. 12 is a cross-sectional view of the image sensor 100C of FIG. 11.

Referring to FIGS. 11 and 12, the transmission gate TG is a merged dual-type transmission gate. For example, the second portion TG_2 of the transmission gate TG, which is arranged in the first semiconductor substrate 110, may include the first gate TG_L and the second gate TG_R, which are apart from each other, and the first portion TG_1 of the transmission gate TG, which is arranged on the first surface 110F1 of the first semiconductor substrate 110, may be formed to be connected integrally with both the first gate TG_L and the second gate TG_R, which are apart from each other.

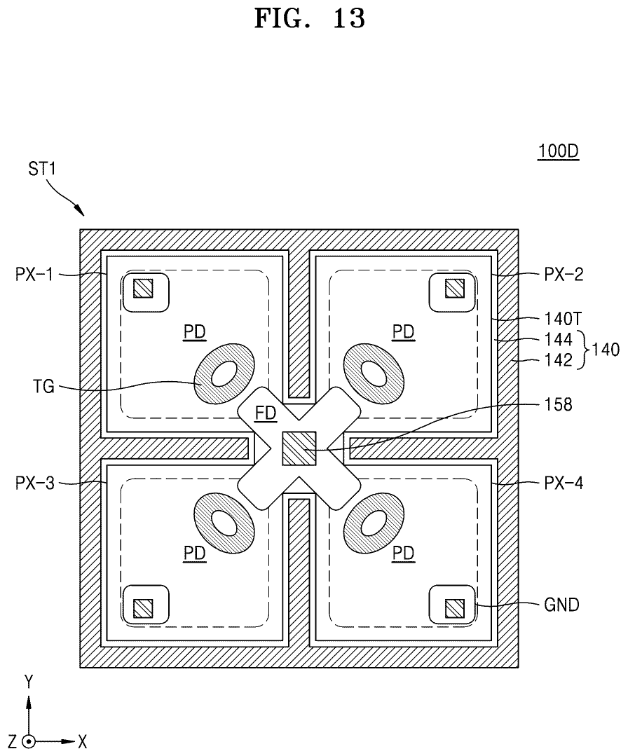

FIG. 13 is a layout diagram illustrating an image sensor 100D.

Referring to FIG. 13, the transmission gate TG is a gate-all-around-type transmission gate. For example, the transmission gate TG may have a horizontal cross-section of a ring shape or an annular shape. The second portion TG_2 (see FIG. 5) of the transmission gate TG, which is arranged in the transmission gate trench TGH, may have a horizontal cross-section of a ring shape or an annular shape, and/or the first portion TG_1 (see FIG. 5) of the transmission gate TG, which is arranged on the first surface 110F1 of the first semiconductor substrate 110, may have a horizontal cross-section of a ring shape or an annular shape.

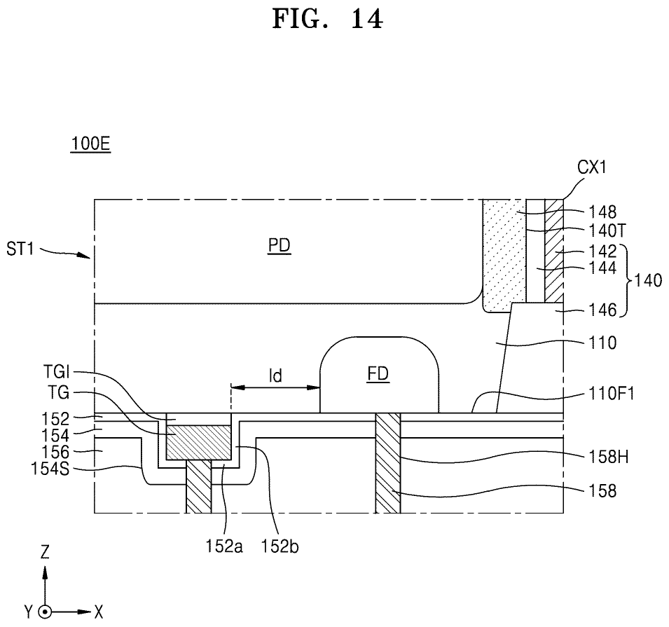

FIG. 14 is a layout diagram illustrating an example of an image sensor 100E.

Referring to FIG. 14, the transmission gate TG is a gate of a planar transistor. For example, the transmission gate TG may be arranged over the first surface 110F1 of the first semiconductor substrate 110, and the transmission gate insulating layer TGI may be arranged between the transmission gate TG and the first surface 110F1 of the first semiconductor substrate 110 to extend in the horizontal direction.

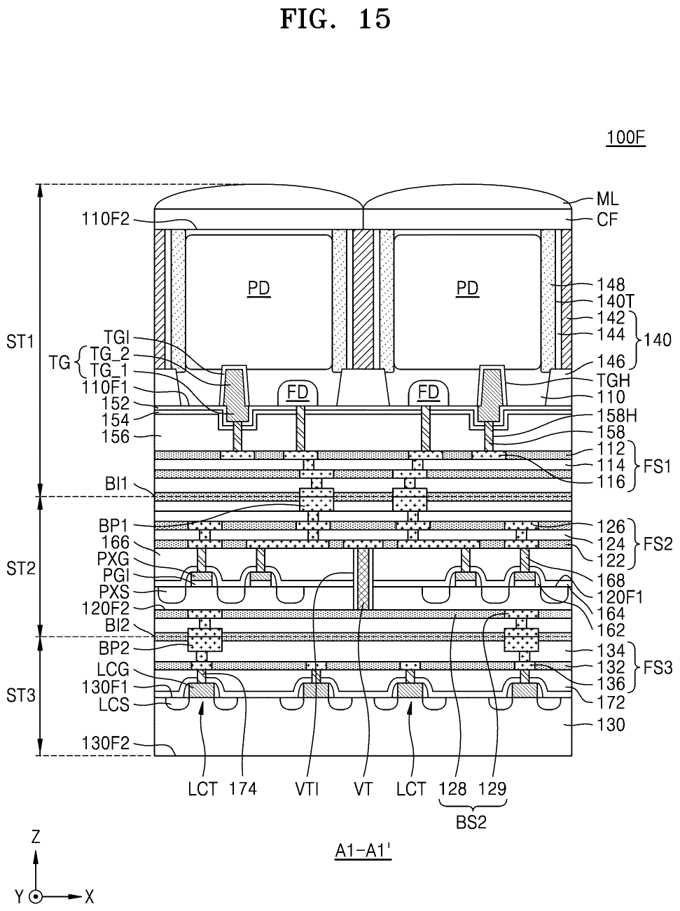

FIG. 15 is a cross-sectional view illustrating an example of an image sensor 100F.

Referring to FIG. 15, the first surface 120F1 of the second semiconductor substrate 120 is arranged to face the first surface 110F1 of the first semiconductor substrate 110, and the second frontside structure FS2 over the first surface 120F1 of the second semiconductor substrate 120 is arranged adjacent to the first frontside structure FS1 over the first surface 110F1 of the first semiconductor substrate 110. The first bonding insulating layer BI1 and the first bonding pad BP1 may be arranged in an interface region between the second frontside structure FS2 and the first frontside structure FS1.

The second surface 120F2 of the second semiconductor substrate 120 may be arranged to face the first surface 130F1 of the third semiconductor substrate 130, and the backside structure BS2 on the second surface 120F2 of the second semiconductor substrate 120 may be arranged adjacent to the third frontside structure FS3 over the first surface 130F1 of the third semiconductor substrate 130. The second bonding insulating layer BI2 and the second bonding pad BP2 may be arranged in an interface region between the backside structure BS2 and the third frontside structure FS3. The backside structure BS2 may include a backside insulating layer 128 and a wiring layer 129.

The second stack ST2 may further include the vertical via VT, which passes through the second semiconductor substrate 120 to electrically connect the backside structure BS2 to the second frontside structure FS2. The vertical via VT may be arranged in the vertical via trench VTH, which extends in the vertical direction (Z direction) through the second semiconductor substrate 120, and the wiring layer 129 on the second surface 120F2 of the second semiconductor substrate 120 and the wiring layer 126 of the second frontside structure FS2 may be electrically connected to each other by the vertical via VT. The vertical via insulating layer VTI may be arranged on the sidewall of the vertical via VT to electrically isolate the vertical via VT and the second semiconductor substrate 120 from each other.

In some implementations, the pixel gate PXG of the second stack ST2 may be electrically connected to the logic transistor LCT of the third stack ST3 through the vertical via VT.

Technical features in at least one of the implementations of the image sensors 100A, 100B, 100C, 100D, 100E, and 100F described above with reference to FIGS. 8 to 15 may be employed in combination with technical features in at least one other implementation. For example, the image sensor 100A described with reference to FIG. 8 may be modified such that stacking is performed to allow the first surface 120F1 of the second semiconductor substrate 120 to face the first surface 110F1 of the first semiconductor substrate 110 as described with reference to FIG. 15. In addition, the image sensors 100B, 100C, 100D, and 100E described with reference to FIGS. 9 to 14 may each be modified such that stacking is performed to allow the first surface 120F1 of the second semiconductor substrate 120 to face the first surface 110F1 of the first semiconductor substrate 110 as described with reference to FIG. 15.

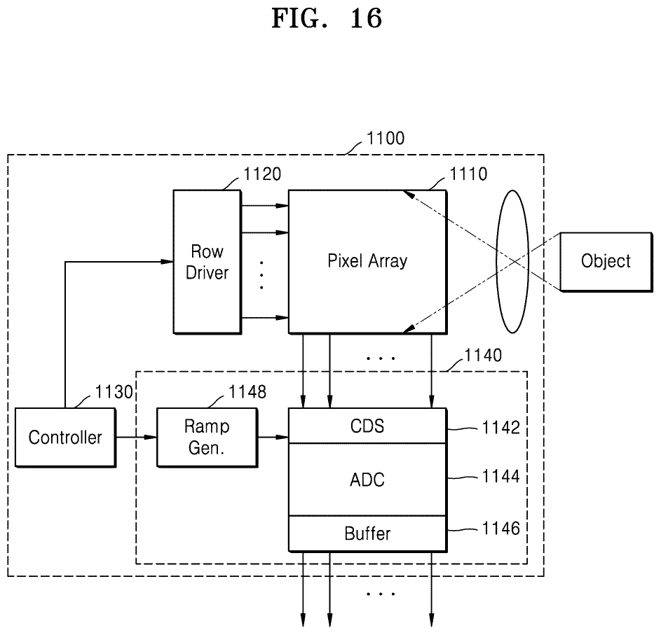

FIG. 16 is a block diagram illustrating a configuration of an example of an image sensor 1100.

Referring to FIG. 16, the image sensor 1100 includes a pixel array 1110, a controller 1130, a row driver 1120, and a pixel signal processing unit 1140. The image sensor 1100 includes at least one of the image sensors 100, 100A, 100B, 100C, 100D, 100E, and 100F described with reference to FIGS. 1 to 15.

The pixel array 1110 may include a plurality of unit pixels that are 2-dimensionally arranged, and each unit pixel may include a photoelectric conversion device. The photoelectric conversion device may generate charges by absorbing light, and an electrical signal (output voltage) according to the generated charges may be provided to the pixel signal processing unit 1140 through a vertical signal line. The unit pixels of the pixel array 1110 may each provide one output voltage at a time on a row basis, and thus, unit pixels of one row of the pixel array 1110 may be simultaneously activated by a selection signal that is output by the row driver 1120. Unit pixels of a selected row may each provide an output voltage according to absorbed light to an output line of a column corresponding thereto.

The controller 1130 may control the pixel array 1110 to absorb light and accumulate charges or to temporarily store the accumulated charges and may control the row driver 1120 to output an electrical signal according to the stored charges to the outside of the pixel array 1110. In addition, the controller 1130 may control the pixel signal processing unit 1140 to measure the output voltage provided by the pixel array 1110.

The pixel signal processing unit 1140 may include a CDS 1142, an analog-to-digital converter (ADC) 1144, and a buffer 1146. The CDS 1142 may sample and hold the output voltage provided by the pixel array 1110. The CDS 1142 may double-sample a specific noise level and a level according to the generated output voltage and thus output a level corresponding to the difference therebetween. In addition, the CDS 1142 may receive ramp signals generated by a ramp signal generator 1148 and compare the ramp signals with each other to output a result of the comparison.

The ADC 1144 may convert an analog signal, which corresponds to the level received from the CDS 1142, into a digital signal. The buffer 1146 may latch digital signals, and the latched digital signals may be sequentially output to the outside of the image sensor 1100 and thus be transferred to an image processor (not shown).

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination.

While the detailed description has been particularly shown and described with reference to embodiments thereof, it will be understood that various changes in form and details may be made therein without departing from the spirit and scope of the following claims.

What is claimed is:

1. An image sensor comprising:
a first stack comprising
a first semiconductor substrate having a first surface and a second surface that is opposite to the first surface,
a photoelectric conversion region in the first semiconductor substrate,
a floating diffusion region arranged in the first semiconductor substrate and configured to store charges transferred from the photoelectric conversion region,
a transmission gate on the first surface of the first semiconductor substrate, and
a first etch stop film arranged on an upper surface and a sidewall of the transmission gate and on the first surface of the first semiconductor substrate;
a second stack, attached to the first stack, the second stack comprising
a second semiconductor substrate having a first surface and a second surface that is opposite to the first surface,
a pixel gate arranged on the first surface of the second semiconductor substrate or on the second surface of the second semiconductor substrate, the pixel gate being electrically connected with the floating diffusion region, and
a gate spacer on a sidewall of the pixel gate; and
a third stack, attached to the second stack and comprising a logic transistor configured to provide signals to the pixel gate and to the transmission gate.

2. The image sensor of claim 1, wherein no spacer is arranged on both sidewalls of the transmission gate.

3. The image sensor of claim 1, wherein the transmission gate is spaced apart from the floating diffusion region in a horizontal direction.

4. The image sensor of claim 1, wherein the sidewall of the transmission gate is perpendicular to the first surface of the first semiconductor substrate, and the first etch stop film is conformally arranged on the upper surface and the sidewall of the transmission gate.

5. The image sensor of claim 1, wherein the transmission gate comprises:
a first portion on the first surface of the first semiconductor substrate; and
a second portion arranged in a transmission trench and integrally connected with the first portion, the transmission trench extending from the first surface of the first semiconductor substrate to an inside of the first semiconductor substrate.

6. The image sensor of claim 5, wherein the first stack further comprises a transmission gate insulating layer on an inner wall of the transmission trench and between the first semiconductor substrate and the second portion of the transmission gate.

7. The image sensor of claim 1, wherein the first stack further comprises a passivation layer between the first etch stop film and each of the upper surface and the sidewall of the transmission gate and also between the first etch stop film and the first surface of the first semiconductor substrate.

8. The image sensor of claim 7, wherein a thickness of a first portion of the passivation layer, which is arranged on the upper surface of the transmission gate, is equal to a thickness of a second portion of the passivation layer, which is arranged on the sidewall of the transmission gate.

9. The image sensor of claim 7, wherein a portion of the first etch stop film, which is arranged on the sidewall of the transmission gate, has a sidewall extending perpendicular to the first surface of the first semiconductor substrate.

10. The image sensor of claim 7, wherein the passivation layer and the first etch stop film extend onto the floating diffusion region.

11. The image sensor of claim 1, wherein the second stack further comprises a second etch stop film arranged on an upper surface of the pixel gate and a sidewall of the gate spacer.

12. An image sensor comprising:
a first stack, comprising
a first semiconductor substrate comprising a first surface and a second surface that is opposite to the first surface,
a photoelectric conversion region in the first semiconductor substrate,
a floating diffusion region arranged in the first semiconductor substrate and configured to store charges transferred from the photoelectric conversion region,
a transmission gate on the first surface of the first semiconductor substrate, and
a first etch stop film arranged on an upper surface of a first portion of the transmission gate, on a sidewall of the first portion of the transmission gate, and on the first surface of the first semiconductor substrate;
a second stack, attached to the first stack, comprising:
a second semiconductor substrate including a first surface and a second surface that is opposite to the first surface, and
a pixel gate arranged on the first surface of the second semiconductor substrate or on the second surface of the second semiconductor substrate, the pixel gate being electrically connected with the floating diffusion region; and
a third stack, attached to the second stack, the third stack comprising a logic transistor configured to provide signals to the pixel gate and the transmission gate,
wherein a portion of the first etch stop film, which is arranged on the sidewall of the transmission gate, has a sidewall extending perpendicular to the first surface of the first semiconductor substrate.

13. The image sensor of claim 12, wherein the first stack further comprises:
a transmission gate insulating layer, which is arranged on an inner wall of a transmission trench and between the first semiconductor substrate and a second portion of the transmission gate; and
a passivation layer, which is arranged between the first etch stop film and each of the upper surface and the sidewall of the first portion of the transmission gate and between the first etch stop film and the first surface of the first semiconductor substrate.

14. The image sensor of claim 13, wherein a thickness of a first portion of the passivation layer, which is arranged on the upper surface of the first portion of the transmission gate, is equal to a thickness of a second portion of the passivation layer, which is arranged on the sidewall of the first portion of the transmission gate.

15. The image sensor of claim 13, wherein the transmission gate is arranged to be spaced apart from the floating diffusion region in a horizontal direction, and the passivation layer and the first etch stop film extend onto the floating diffusion region.

16. The image sensor of claim 13, wherein the second stack further comprises:
a gate spacer on a sidewall of the pixel gate; and
a second etch stop film arranged on an upper surface of the pixel gate and a sidewall of the gate spacer.

17. The image sensor of claim 13, wherein no spacer is arranged on both sidewalls of the transmission gate.

18. An image sensor comprising a first stack, a second stack attached to the first stack, and a third stack attached to the second stack,
wherein the first stack comprises a first semiconductor substrate comprising
a first surface and a second surface that is opposite to the first surface,
a photoelectric conversion region in the first semiconductor substrate,
a floating diffusion region arranged in the first semiconductor substrate and configured to store charges transferred from the photoelectric conversion region,
a transmission gate arranged on the first surface of the first semiconductor substrate and having a first portion and having a second portion that is arranged in a transmission trench extending to an inside of the first semiconductor substrate,
a first etch stop film arranged on an upper surface and a sidewall of the first portion of the transmission gate and on the first surface of the first semiconductor substrate, and
a passivation layer arranged between the first etch stop film and each of the upper surface and the sidewall of the first portion of transmission gate and between the first etch stop film and the first surface of the first semiconductor substrate,
wherein the second stack comprises a second semiconductor substrate comprising
a first surface and a second surface that is opposite to the first surface,
a pixel gate arranged on the first surface of the second semiconductor substrate or on the second surface of the second semiconductor substrate, the pixel gate being electrically connected with the floating diffusion region,
a gate spacer on a sidewall of the pixel gate, and
a second etch stop film arranged on an upper surface of the pixel gate and on a sidewall of the gate spacer, and
wherein the third stack includes a logic transistor configured to provide signals to the pixel gate and the transmission gate.

19. The image sensor of claim 18, wherein no spacer is arranged on both sidewalls of the transmission gate, and the passivation layer and the first etch stop film extend onto the floating diffusion region.

20. The image sensor of claim 18, wherein a thickness of a first portion of the passivation layer, which is arranged on the upper surface of the first portion of the transmission gate, is equal to a thickness of a second portion of the passivation layer, which is arranged on the sidewall of the first portion of the transmission gate, and
wherein a portion of the first etch stop film, which is arranged on the sidewall of the first portion of the transmission gate, has a sidewall extending perpendicular to the first surface of the first semiconductor substrate.
